(19) United States
(12) Patent Application Publication
(10) Pub. No.: US 2022/0360896 A1
(43) Pub. Date: Nov. 10, 2022

(54) MODULAR CONFERENCING SYSTEM

(71) Applicant: Facebook Technologies, LLC, Menlo Park, CA (US)

(72) Inventors: Stephen Mark Jeapes, Cambridge (GB); Howard William Winter, Southampton (GB)

(21) Appl. No.: 17/313,656

(22) Filed: May 6, 2021

(51) Int. Cl. H04R 3/12; H04R 5/02; H04N 7/15; H04R 1/02; G10L 21/0232; H04R 5/04; H03F 3/183

(52) U.S. Cl. CPC H04R 3/12; H04R 5/02; H04N 7/15; H04R 1/028; G10L 21/0232; H04R 5/04; H03F 3/183; H04R 2499/15; G10L 2021/02082

(57) ABSTRACT

In some examples, a conferencing system includes a modular electronic device having a device housing configured to removably couple to each of a plurality of speaker modules; amplifier circuitry disposed within the device housing, wherein the amplifier circuitry is configured to amplify audio signals for output to a speaker module of the plurality of speaker modules while the electronic device is coupled to the speaker module; and processing circuitry disposed within the device housing, wherein the processing circuitry is configured to: determine one or more parameters associated with the speaker module after the device housing is coupled to the speaker module; and determine, based on the one or more parameters associated with the speaker module, a set of corresponding audio-configuration settings for processing audio during operation of the conferencing system.

### TECHNICAL FIELD

This disclosure generally relates to electronic devices, and more particularly, to communication systems with audio-communication capabilities.

### BACKGROUND

Video-telephony technology, including videoconferencing, video-chat tools and services, etc., is becoming an increasingly popular way for friends, families, colleagues, and other groups of people to communicate with each other. Camera hardware and microphones are present in or usable with various end-user devices, such as smartphones, head-mounted devices (HMDs), tablet computers, laptop computers, network-connected televisions (e.g., “smart TVs”), digital displays (e.g., computer displays), whether as integrated hardware or as add-on hardware. The incorporation of camera hardware into connected devices enables videoconferencing with others using any of a number of online video-telephony services.

### SUMMARY

In general, this disclosure describes communication systems with audio and/or video capabilities that include one or more manually interchangeable modular components. More specifically, in some examples, this disclosure describes an electronic device for an audio-conferencing system, wherein the electronic device is configured to removably couple to each of a plurality of different types of speaker modules. In some such examples, while coupled to a particular speaker module, the electronic device is configured to determine one or more parameters associated with the speaker module (e.g., physical specifications or the speaker module and/or the environment in which the speaker module is located) and in response, select and enable customized functionality based on the speaker parameters. For instance, the electronic device may be configured to customize audio-output parameters to complement the parameters associated with the speaker. In some instances, based on the speaker parameters, the electronic devices of this disclosure set digital signal-processing (DSP) parameters, such as echo-cancellation parameters, audio-equalization parameters, and the like, for audio data being output, or for audio data to be output, by the connected speaker module of the conferencing system.

Communication systems of this disclosure may implement one, some, or all of the functionalities described above in various use cases consistent with this disclosure. Moreover, the communication systems of this disclosure may dynamically update one or more of the audio-related parameters listed above in response to identifying different speaker parameters (e.g., a different type of connected speaker module and/or a different local physical environment).

In one example, an electronic device for a conferencing system includes a device housing configured to removably couple to each of a plurality of speaker modules; and processing circuitry disposed within the device housing, wherein the processing circuitry is configured to: determine one or more parameters associated with a speaker module of the plurality of speaker modules after the device housing is coupled to the speaker module; and determine, based on the one or more parameters associated with the speaker module, a set of corresponding audio-configuration settings for processing audio during operation of the conferencing system.

In another example, a conferencing system includes a speaker module and an electronic device comprising: a device housing configured to removably couple to the speaker module; and processing circuitry disposed within the device housing, wherein the processing circuitry is configured to: determine one or more parameters associated with the speaker module after the device housing is coupled to the speaker module; and determine, based on the one or more parameters associated with the speaker module, a set of corresponding audio-configuration settings for processing audio during operation of the conferencing system.

In another example, a non-transitory computer-readable storage medium stores one or more programs configured for execution by one or more processors of an electronic device. The one or more programs include instructions that, when executed by the one or more processors, cause the electronic device to: determine one or more parameters associated with a speaker module after the electronic device is removably coupled to the speaker module; and determine, based on the one or more parameters associated with the speaker module, a set of corresponding audio-configuration settings for processing audio during operation of a conferencing system comprising the speaker module, wherein the audio-configuration settings comprise at least echo-cancellation settings.

The techniques and system configurations of this disclosure may provide one or more technical improvements in the technology area of communication systems, such as audioconferencing systems, videoconferencing systems, or the like. As one example, the configurations of this disclosure may improve audio quality by selecting customized audio-processing based on unique parameters of each type of speaker module. The configurations of this disclosure may be advantageous in a number of scenarios. For example, the modular configurations of this disclosure may be advantageous in scenarios in which a consumer or other user wishes to select particular components based on his or her unique needs. This may be particularly advantageous in large organizations with many conference rooms, as the organization may keep an inventory of a reduced number of products since a single electronics device may be used with multiple, different speaker modules. As another example, the techniques of this disclosure may reduce one or more costs associated with both the production and the purchase of conferencing systems. For example, a single electronic device and a plurality of different “passive” speaker modules, each with limited internal components (e.g., electronics), may be substantially cheaper to produce than an equal number of fully functional speaker modules. Accordingly, the techniques of the disclosure provide specific technical improvements to the computer-related and network-related field of conferencing systems.

The details of one or more examples of the techniques of this disclosure are set forth in the accompanying drawings and the description below. Other features, objects, and advantages of the techniques will be apparent from the description and drawings, and from the claims.

### BRIEF DESCRIPTION OF DRAWINGS

FIG. 1A is an illustration depicting an example conferencing system engaged in an audiovisual-communication session, in accordance with techniques of the disclosure.

FIG. 1B is an illustration depicting another example conferencing system and its surrounding environment, in accordance with techniques of the disclosure.

FIG. 2 is a block diagram illustrating an example of a modular electronic device of the conferencing systems of FIGS. 1A and 1B.

FIG. 3 illustrates an example of the electronic device of FIG. 2 while removably coupled to a speaker module, in accordance with techniques of this disclosure.

FIG. 4A is a perspective overhead view, and FIG. 4B is a side view, of the electronic device of FIG. 3 removably coupled to the speaker module.

FIG. 5 is an example desk setup that includes an electronic device coupled to a speaker module.

FIG. 6 is another example of an electronic device that includes mounting brackets.

FIG. 7 illustrates an example use case of the electronic device of FIG. 6 mounted behind a TV, such as in a relatively larger conference room.

FIG. 8 is a flowchart illustrating an example of an audio-configuration process that the electronic devices of any of FIGS. 1A-7 may perform, in accordance with aspects of this disclosure.

Like reference characters refer to like elements throughout the drawings and description.

### DETAILED DESCRIPTION

Conferencing services, such as multi-use communication packages that include conferencing components, transport video data and audio data between two or more participants, enabling real-time or substantially real-time (e.g., near real-time) communications between participants who are not located at the same physical site. Conferencing services are ubiquitous as a communication medium in private-sector enterprises, for educational and professional training/instruction, and for government-to-citizen information dissemination, among other uses. With conferencing services being used for important types of communication, the focus on data precision and service reliability is also becoming more acute.

This disclosure is directed to configurations for conferencing systems, such as video-telecommunication hardware, that include one or more modular, interchangeable components and in particular, an electronic device (e.g., encapsulated control circuitry) configured to removably couple to each of a plurality of different type of speaker modules that lack integrated control circuitry. The speaker modules may be passive, in that they include only passive electronic components and drivers, or may be active, in that they include one or more amplifiers configured to drive the speaker drivers. While coupled (physically or wirelessly) to a particular speaker module, the electronic device is configured to determine one or more parameters associated with the speaker module (also referred to herein as “speaker parameters”). The speaker parameters may define a “type” of the speaker module, such as a particular manufactured model of speaker module and its corresponding technical specifications. Additionally, or alternatively, the speaker parameters may provide an indication of a physical environment in which the speaker module is located, e.g., indoors or outdoors, a size and or shape of a room, a number of speaker modules installed in the room, etc.

Based on the one or more speaker parameters, the electronic device is configured to determine a corresponding set of customized audio-configuration settings for processing audio during operation of the conferencing system, e.g., to improve the precision with which audio data of communication sessions are rendered for playback to the local participant(s). For instance, the audio-configuration settings may include DSP parameters used to manipulate the audio signals to control at least echo-cancellation in order to complement the particular type of speaker module and associated microphone(s). Other example determinable DSP parameters may include frequencies, amplitudes, and/or phases of the output audio signals.

While described primarily in the context of conferencing technology in this disclosure as an example, it will be appreciated that the techniques of this disclosure may implemented in other types of systems as well. For example, the configurations of this disclosure may be implemented in artificial reality systems. Artificial reality is a form of reality that has been adjusted in some manner before presentation to a user, and may include one or more of virtual reality (VR), augmented reality (AR), extended reality (XR), mixed reality (MR), hybrid reality, or some combination and/or derivative thereof. For instance, artificial reality systems that incorporate the audio-data-manipulation techniques of this disclosure may update audio data captured and/or rendered for playback via a head-mounted device (HMD) or other devices incorporating speaker hardware combined with hardware configured to display artificial reality content in visual form.

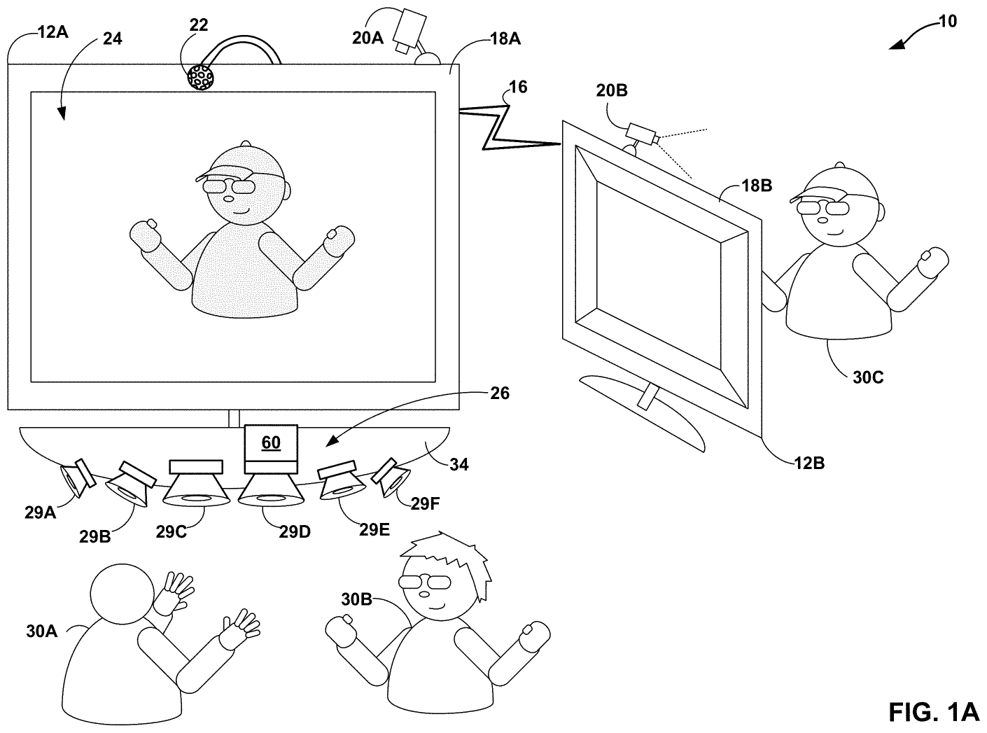

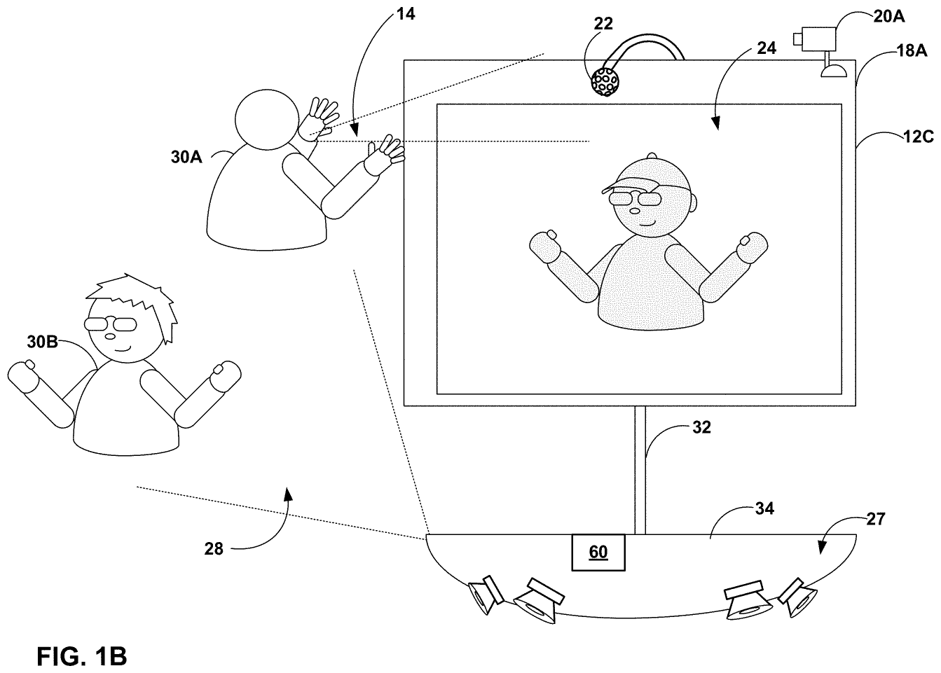

FIG. 1A is an illustration depicting an example conferencing system 10 including audiovisual conferencing systems 12A, 12B (collectively, “audiovisual conferencing systems 12”) engaged in a conferencing session. In the example of FIG. 1A, audiovisual conferencing systems 12 are engaged in a videoconferencing session, and both of audiovisual conferencing systems 12 include video-input and video-output capabilities. In other examples, aspects of this disclosure may be applied in the context of audio conferencing, such as standalone audio conferencing or combined audio/videoconferencing, and may be applied seamlessly across switches between the two (e.g., if video capabilities are temporarily disabled due to bandwidth issues, etc.).

Audiovisual conferencing systems 12 of FIG. 1A are shown for purposes of example, and may represent any of a variety of devices with audio and/or audio/video telephonic capabilities, such as a mobile computing device, laptop, tablet computer, smartphone, server, stand-alone tabletop device, wearable device (e.g., smart glasses, an artificial reality HMD, or a smart watch) or dedicated audio and/or videoconferencing equipment. As described herein, conferencing system 10 (e.g., at least one of audiovisual conferencing systems 12) includes one or more modular components configured to set audio-rendering parameters and/or echo-cancellation parameters, based on determined parameters associated with a speaker module configured to output the audio, and to which the modular component is presently removably coupled or connected.

In the example of FIG. 1A, conferencing system 10 includes a first audiovisual conferencing system 12A connected to a second conferencing telephonic system 12B over a communications channel 16. Each audiovisual conferencing system 12A, 12B includes one of display devices 18A and 18B and image-capture systems 20A and 20B (collectively, “image-capture systems 20” or in the alternative, “image-capture system 20”). Each image-capture system 20 is equipped with image-capture capabilities (often supplemented with, and sometimes incorporating, one or more microphones providing voice-capture capabilities). Each image-capture system 20 includes camera hardware configured to capture still images and moving pictures of the surrounding environment.

Conferencing system 10 may in some cases be in communication, via a network, with one or more compute nodes (not shown) that correspond to computing resources in any form. Each of the compute nodes may be a physical computing device or may be a component of a cloud computing system, server farm, and/or server cluster (or portion thereof) that provides services to client devices and other devices or systems. Accordingly, any such compute nodes may represent physical computing devices, virtual computing devices, virtual machines, containers, and/or other virtualized computing device. The compute nodes may receive, process, and output video to perform techniques described herein. The compute nodes may be located at or otherwise supported by various high-capacity computing clusters, telecommunication clusters, or storage systems, such as systems housed by data centers, network operations centers, or internet exchanges.

In the example shown in FIG. 1A, participants 30A and 30B share and use audiovisual conferencing system 12A to communicate over communications channel 16 with participant 30C operating audiovisual conferencing system 12B. Audiovisual conferencing system 12A includes display device 18A and image-capture system 20A, while audiovisual conferencing system 12B includes display device 18B and image-capture system 20B. In various implementations, image capture system 20A and display device 18A may be included in a single device or may be separated into separate devices.

Display devices 18 and image-capture systems 20 are configured to operate as video-communication equipment for audiovisual telephonic systems 12A, 12B. That is, participants 30A and 30C may communicate with one another in an audio and/or videoconferencing session over communications channel 16 using display devices 18 and image-capture systems 20. Image capture systems 20A and 20B capture still and/or moving pictures of participants 30A-30C, respectively. Computing hardware and network interface hardware of audiovisual conferencing systems 12A and 12B process and transmit the captured images substantially in real-time over communications channel 16.

Communications channel 16 may be implemented over a private network (e.g., a local area network or LAN), a public network (e.g., the Internet), a private connection implemented on public network infrastructure (e.g., a virtual private network or VPN tunnel implemented over an Internet connection), other type of packet-switched network, etc. Network interface hardware and computing hardware of the audiovisual conferencing systems 12A and 12B receive and process the images (e.g., video streams) transmitted over communications channel 16. Display devices 18 are configured to output image data (e.g., still images and/or video feeds) to participants 30, using the image data received over communications channel 16 and processed locally for rendering and output.

In this way, audiovisual conferencing systems 12A and 12B, by way of image-capture systems 20 and display devices 18, enable participants 30 to engage in a videoconferencing session. While the videoconferencing session implemented over conferencing system 10 is illustrated in FIG. 1A as including two actively communicating devices as one non-limiting example, it will be appreciated that the systems and techniques of this disclosure are scalable, in that videoconferencing sessions of this disclosure may accommodate any number of participating devices, such as three or more participating devices, in some scenarios. The systems and techniques of this disclosure are also compatible with videoconferencing sessions with in-session variance in terms of the number of participants, such as videoconferencing sessions in which one or more participants are added and removed throughout the lifetime of the session.

In the example of FIG. 1A, display device 18A outputs display content 24 to participants 30A, 30B. Display content 24 represents a still frame of a moving video sequence output to participants 30A, 30B as part of the videoconferencing session presently in progress. Display content 24 includes a visual representation of participant 30C, who is a complementing participant to participant 30A in the video-telephonic session. In some examples, display content 24 may also include a video feedthrough to provide an indication of how the image data captured by image-capture system 20A appears to other users in the video-telephonic session, such as to participant 30C via display device 18B. As such, a video feedthrough, if included in display content 24, would provide participants 30A, 30B with a low-to-zero time-lagged representation of the image data attributed to the surroundings of audiovisual telephonic system 12A and displayed to other participants in the videoconferencing session.

Audiovisual conferencing systems 12A and 12B may provide privacy settings that facilitate operators of the audiovisual conferencing systems (e.g., participants 30A and 30C, etc.) to individually specify (e.g., by opting out, by not opting in) whether the audiovisual conferencing systems 12A and 12B, or any associated online system, may receive, collect, log, or store particular objects or information associated with the participant for any purpose. For example, privacy settings may allow the participant 30A to specify whether particular video-capture devices, audio-capture devices, applications or processes may access, store, or use particular objects or information associated with participants 30A and 30B. The privacy settings may allow participants 30A and 30C to opt in or opt out of having objects or information accessed, stored, or used by specific devices, applications, or processes for users of respective audiovisual conferencing systems 12A and 12B. Before accessing, storing, or using such objects or information, an online system associated with audiovisual conferencing systems 12A and 12B may prompt the participants 30A and 30C to provide privacy settings specifying which applications or processes, if any, may access, store, or use the object or information prior to allowing any such action. For example, participant 30A or participant 30C may specify privacy settings that audio and visual data should not be stored by audiovisual conferencing systems 12A and 12B and/or any associated online service, and/or audiovisual conferencing systems 12A and 12B and/or any associated online service should not store any metadata (e.g., time of the communication, who participated in the communication, duration of the communication, etc.) and/or text messages associated with use of audiovisual telephonic systems 12A and 12B. Additionally or alternatively, audiovisual conferencing systems 12A and 12B to selectively mute (e.g., prevent capture of or output of) video and/or audio capture data.

Audiovisual conferencing systems 12A and 12B systems 12A, 12B also enable audio communication between participants 30A-30C, alone, or substantially in synchrony (e.g., with low-to-zero offset) with the video feeds described above. Each of audiovisual conferencing systems 12A, 12B incorporate audio-capture hardware to capture audio communications provided by the local participant(s) 30A-30C, and audio-output hardware to output audio communications received over communications channel 16. As shown in FIG. 1A, audiovisual conferencing system 12A includes (or is communicatively coupled to) each of microphone array 22 and speaker array 26, including one or more individual speaker modules 26A-26F. Audiovisual conferencing system 12B may also include or be coupled to corresponding microphone hardware and/or speaker hardware, but these devices are not explicitly shown or numbered in FIG. 1A for ease of illustration based on the illustrated perspective of audiovisual conferencing system 12B.

Microphone array 22 represents a data-input component that includes one or more microphone(s) configured to capture audio data from the surrounding environment of audiovisual conferencing system 12A. In the particular example of FIG. 1A, microphone array 22 is constructed as a cluster of individual microphones disposed on the surface of a substantially spherical ball, which, in turn, is connected to the rest of audiovisual conferencing system 12A via a “gooseneck”-type mount or stand. In other examples, the individual microphone(s) of microphone array 22 may be integrated into the periphery of display device 18A, speaker array 26, or both, such as along the top edge of display device 18A, a top of speaker array 26, or the like.

In some examples, microphone array 22 may represent a multi-microphone array, with at least some of the multiple individual microphones being fixedly mounted relative to a component of audiovisual conferencing system 12A, such as a top edge or panel of display device 18A. In some examples, the multi-microphone array may include four microphones, and the four individual microphones of microphone array 22 may be arranged in the general shape of a truncated pyramid array. In other examples, the individual microphones of microphone array 22 may be positioned on/within/near the remaining components of audiovisual conferencing system 12A in other ways. In any event, the relative positions of the individual microphones of microphone array with respect to one another may be fixed, regardless of the orientation of display device 18A. Additionally, in some examples, relative positions of the individual microphones of microphone array 22 may be fixed relative to a component of audiovisual conferencing system 12A, e.g., may be fixed relative to display device 18A. For instance, microphone array 22 may be fixedly attached to a portion of display device 18A, such as a bezel of display device 18A.

In some examples, microphone array 22 may capture not only audio data, but additional metadata describing various attributes of the captured audio data, as well. For instance, microphone array 22 may capture a combination of audio data and directional data. In these examples, microphone array 22 may be collectively configured to capture a three-dimensional sound field in the immediate vicinity of audiovisual conferencing system 12A.

Whether captured directly by microphone array 22 or indirectly extrapolated from the collective audio signals (e.g. via audio beamforming, etc.) by digital signal processing (DSP) logic of audiovisual conferencing system 12A, audiovisual conferencing system 12A may associate directionality information with the audio data captured by each individual microphone of microphone array 22. As such, audiovisual conferencing system 12A may attach directionality information, whether determined indirectly by the DSP logic or received directly from microphone array 22, to one or more audio signals received from microphone array 22. In other words, audiovisual conferencing system 12A may process the various audio signals captured by microphone array 22 to be one-dimensional, or to have two-dimensional diversity, or to have three-dimensional diversity, depending on which individual microphones of microphone array 22 detect sound inputs of a threshold acoustic energy (e.g., sound intensity or loudness) at a given time.

Display device 18A may be rotated about one or more of an X axis (pitch), Y axis (yaw), or Z axis (roll), thereby changing the directionality (or directional diversity) with respect to the audio signals captured by the various microphones of microphone array 22. Display device 18A may, in some examples, also be moved translationally, such as by sliding alongside panels and/or top and bottom panels that enable translational movement. As used herein, “rotational” and/or “translational” movement of display device 18A refer to orientation changes of display device with respect to an otherwise stationary component of audiovisual conferencing system 12A, such as base 34. The DSP logic or other audio-processing hardware of audiovisual conferencing system 12A may encode or transcode the audio data and packetize the encoded/transcoded data for transmission over a packet-switched network, such as over communications channel 16.

Audiovisual conferencing system 12A also includes speaker module 26, as shown in FIG. 1A. Speaker module 26 includes a plurality of drivers 29A-29F (collectively, “drivers 29”).

In some examples, speaker module 26 may be included within other components of audiovisual conferencing system 12A in various examples. For instance, speaker module 26 may be physically incorporated into another component (e.g., speaker base 34) of audiovisual conferencing system 12A. In other examples, speaker module 26 may be a standalone device. Speaker module 26 may include various types of drivers 29, such as piezoelectric drivers that are commonly incorporated into computing devices. In some examples, speaker module 26 may include one or more cone drivers and, optionally, ports, acoustic transmission lines, and/or passive radiators. In some examples that include passive radiators, the passive radiators may be horizontally opposed, and move out of phase with each other to help dampen/cancel vibrations due to low frequencies output by the passive radiators. In some examples, speaker module 26 includes a speaker box (e.g., an external housing and other mechanical components of the speaker module 26)

Speaker module 26 may, in some examples, include speakers in separate housings, which speakers have the same audio output capabilities, such as a pair or an array of full-range speakers. In some examples, speaker module 26 may include at least two speakers with different audio-output capabilities, such as two or more of subwoofers, woofers, mid-range drivers, or tweeters. Speaker module 26 may incorporate speakers with different types of connectivity capabilities, such as wired speakers, or wireless speakers, or both.

In some examples, speaker module 26 may include or may be a passive speaker module. As used herein, a “passive” speaker module refers to a device having most or all of the mechanical components of a typical audio-output device (e.g., a housing, cone, diaphragm, dust cover/cap, suspension, voice coil, cone neck fill, chassis, suspension neck fill, basket, front plate, spider, magnet, yoke, etc.), but few or none of the typical electronic components of a fully functional speaker unit. For example, passive speaker modules as described herein may be lacking in one or more of processing circuitry, control circuitry, DSP logic, crossover components, or other audio-processing hardware from within the speaker housing.

In other examples, speaker module 26 may include or may be an active speaker module. As used herein, an “active” speaker module refers to a device having most or all of the mechanical components of a typical audio-output device and one or more amplifiers for amplifying received audio signals for output by the speaker module. In some examples, an active speaker may lack crossover components and control components for manipulating the audio signals prior to output to the one or more amplifiers.

According to the techniques described herein, conferencing system 10 includes a modular electronic device 60 configured to supply the audio-processing hardware lacking from the speaker module 26. That is, electronic device 60 is configured to removably couple to speaker module 26 of conferencing system 10 to provide both electrical power and audio-processing functionality, including at least echo-cancellation, to the speaker module.

For instance, as shown in FIG. 1A, electronic device 60 is depicted as being removably coupled to speaker module 26. Electronic device 60 may include driver logic configured to drive speaker module 26, such as to render audio data for output to participants 30A, 30B. While removably coupled to speaker module 26, the driver logic of electronic device 60 may provide speaker feeds to speaker module 26, and speaker module 26 may render the audio data provided in the feeds as audible sound data.

In this way, audiovisual conferencing system 12A, via electronic device 60, may leverage speaker module 26 to assist participants 30A, 30B in participating in the videoconferencing session over communications channel 16. Audiovisual conferencing system 12A uses microphone array 22 to enable participants 30A, 30B to provide audio data (spoken words/sounds, background music/audio, etc.) to accompany the video feed captured by image-capture system 20A. Similarly, audiovisual telephonic system 12A uses electronic device 60 and speaker module 26 to render audio data that accompanies the moving/still image data shown in display content 24.

FIG. 1B is an illustration depicting another example audiovisual conferencing system 12C and its surrounding environment. In the example of FIG. 1B, electronic device 60 has been removed from speaker module 26 and has been removably coupled to speaker module 27 instead. Electronic device 60 is configured, according to aspects of this disclosure, to manipulate audio-output data to accommodate this type of positional change, as described below in greater detail.

Speaker module 27 outputs audio-output data 28 at the physical location of audiovisual conferencing system 12C. Audio-output data 28 may include (or in some cases, consist entirely of) audio data received by audiovisual conferencing system 12C over communications channel 16 as part of an active conferencing session, e.g., with audiovisual conferencing system 12B (see FIG. 1A). For instance, audio-output data 28 may include audio data that accompanies a video feed that is rendered for display in the form of display content 24. In some instances, even if the video feed is interrupted, causing display content 24 to reflect a freeze frame or default picture, audiovisual conferencing system 12C may continue to drive speaker module 27 to render audio-output data 28, thereby maintaining the audio feed of the currently active conferencing session.

As shown in FIG. 1B, display device 18A is mounted on base 34 by way of stand 32, thereby providing audiovisual conferencing system 12C with upright display capabilities. It will be appreciated that stand 32, base 34, and other components of audiovisual conferencing system 12C are not drawn to scale for all possible use-cases in accordance with this disclosure, and that the aspect ratio shown in FIG. 1B represents only one of many different aspect ratios that are compatible with the configurations of this disclosure. In another example, stand 32 and base 34 may be substantially integrated, and have little-to-no difference in width/circumference.

Electronic device 60 is configured according to aspects of this disclosure to drive speaker module 27 (e.g., the speaker module to which electronic device 60 is presently coupled) to render audio-output data 28 in a modified way based on one or more parameters associated with the coupled speaker module 27 (or “speaker parameters”). The speaker parameters may indicate any dimensions, configurations (e.g., driver complement, driver electromechanical parameters, active or passive speaker module, or the like), or other specifications of the speaker module itself and/or a physical environment in which the speaker module is located, that could affect the quality of audio produced by the speaker module, as perceived by a listener. In some examples, the speaker parameters may include a model identifier that identifies the model of the speaker module. According to some examples of this disclosure, DSP logic of electronic device 60 may modify the processing of individual audio signals (e.g., from audio-input data 14) based on parameters associated with speaker module 27 and/or its local environment to enable rendered audio that complements or corresponds to the parameters. For example, the DSP logic of electronic device 60 may modify audio-input data 14 in a way that fully or partially reduces or cancels an echo (e.g., audio captured by microphone array 22 that corresponds to audio output by speaker module 27) based on the form factor, size, phase and frequency response, impedance, power handling, amplifier power, compliance (cms), quality factor (q), driver mass (M_{MD} and/or M_{MS}) cone surface area (S_{D}), displacement volume (V_{D}), motor strength (B_{L}), air suspension volume (V_{AS}), maximum linear excursion (X_{MAX}), sound pressure level (S_{PL}), and/or other parameters of the mechanical components of speaker module 27, as compared to corresponding parameters of a different speaker module (e.g., speaker module 26 of FIG. 1A) having different values.

According to the techniques herein, electronic device 60 is configured to determine the one or more parameters associated with the speaker module 27 to which electronic device 60 is removably coupled. For instance, when removably coupled to speaker module 27, electronic device 60 is configured to determine the parameters associated with speaker module 27, such as specifications of speaker module 27 and/or the environment in which speaker module 27 is located.

In some examples, electronic device 60 may be configured to determine the parameters associated with speaker module 27 based on a coupling mechanism that interconnects electronic device 60 and speaker module 27. As one non-limiting example, speaker module 27 may include a plurality of connector pins (e.g., spring-loaded pins or “pogo” pins) configured to connect to a corresponding pin-receiving unit disposed on a housing of electronic device 60 (or vice versa). In some such examples, the connector pins of speaker module 27 may be numbered and/or arranged according to a unique configuration that both encodes and conveys to electronic device 60 the set of parameters associated with speaker module 27 when electronic device 60 is removably coupled to the connector pins.

For instance, speaker module 27 may belong to a common type or model of speaker module, defining a common set of physical specifications and other standardized parameters for that model. In some examples, all of the speaker modules of the model to which speaker module 27 belongs may have substantially similar parameters, and accordingly, a substantially identical connector-pin configuration.

In the above-described scenario, different types (e.g., models) of speaker modules may have different parameters (e.g., sizes, specifications, and other configurations). Accordingly, each type of speaker module may include a different (e.g., unique) configuration of connector pins indicating a common set of speaker parameters. As one non-limiting example, the number and arrangement of connector pins for a particular type of speaker module may conform to a binary number, wherein the presence of a connector pin in a particular position indicates a “1” and the absence of a connector pin in a particular position indicates a “0.” In such examples, electronic device 60 is configured to determine the parameters associated with the speaker by “reading” the binary number from the connector pins and then, e.g., comparing the determined binary number to a stored lookup table indicating a corresponding set of audio-modification settings that complement the particular speaker module.

Accordingly, when electronic device 60 is removed or disconnected from a first type of speaker module (e.g., from speaker module 26, as shown in FIG. 1A) and removably coupled to a second type of speaker module (e.g., to speaker module 27, as shown in FIG. 1B), wherein the second type of speaker module includes different associated parameters than the first type of speaker module, electronic device 60 is configured to determine the change in parameters, e.g., based on the change in connector-pin configuration. In response to detecting the new parameters of speaker module 27, the DSP logic of electronic device 60 may modify the one or more audio-processing settings to match or complement the parameters associated with speaker module 27, in order to improve the quality of audio that is rendered and output by speaker module 27. For example, the driver logic of electronic device 60 may compensate for audio-quality changes (e.g., echo-cancellation, frequency, amplitude, and/or phase changes) occurring due to the difference in parameters associated with the different types of speaker modules 26 and 27. In other words, electronic device 60 is configured to determine, select, and/or set audio-configuration settings that include at least one of echo-cancellation, frequency, phase, or delay settings for processing the audio-output data 28 from electronic device 60 to speaker module 27.

For example, the driver logic of electronic device 60 may map the connector-pin configuration to a set of audio-processing settings that include a set of equalization parameters, and drive speaker module 27 to render audio-output data 28 according to the set of equalization parameters. To map an equalization parameter set to the configuration of the connector pins of speaker module 27, the driver logic of electronic device 60 may select, e.g., from memory, the parameter set from a superset of available equalization parameters. Speaker module 27 may in turn render audio-output data 28 according to the set of equalization parameters. In some examples, to map the connector-pin configuration of speaker 27 to the appropriate set of equalization parameters, the driver logic of electronic device 60 utilizes a lookup table that provides a one-to-one or many-to-one mapping of different connector-pin configurations to respective (predetermined) sets of equalization parameters.

In this way, the driver logic of audiovisual conferencing system 12A may drive speaker module 27 to render audio-output data 28 in a way that is customized to the parameters associated with speaker module 27.

As another example, instead of a unique configuration of connector pins that encodes the parameters, speaker module 27 may include an integrated computer-readable medium, such as a memory device, that encodes the parameters associated with the type of speaker module to which speaker module 27 belongs. For instance, an integrated memory unit fixed locally within speaker module 27 may encode any or all of a frequency response, a power level, an electrical impedance, or a topology of speaker module 27. When electronic device 60 is removably coupled to a new speaker module, driver logic of electronic device 60 is configured to scan or read the parameters (or the indication thereof) from the integrated memory of speaker module 27.

According to some examples of this disclosure, electronic device 60 may incorporate acoustic echo-cancellation logic that is configured or selected based on the parameters associated with the connected speaker module 27. The acoustic echo-cancellation logic may be implemented as part of other processing circuitry of electronic device 60, or as part of the DSP logic that implements the manipulation of audio-output data 28 described above, or may represent dedicated hardware or firmware unit(s) of electronic device 60. While described herein as implementing acoustic echo-cancellation as an example, it will be appreciated that electronic device 60 may compensate for feedback or loopback effects of audio-output data 28 with respect to audio-input data 14 in other ways, such as by implementing acoustic echo-suppression logic. In some examples, audiovisual conferencing system 12A may implement other refinement techniques with respect to audio-input data 14, such as active noise cancellation (ANC) to cancel out persistent noises, such as those emanating from ambient devices (air conditioners, etc.) or from other components of audiovisual conferencing system 12A itself (CPU cooling fans, etc.).

In some examples, electronic device 60 may process audio data in a way that improves quality of audio for user 30B. As one illustrative example, electronic device 60 may perform echo cancellation based on an orientation of speaker module 27 relative to microphone array 22, as described in further detail in commonly assigned U.S. patent application Ser. No. 16/897,039, filed Jun. 9, 2020, and incorporated by reference herein in its entirety.

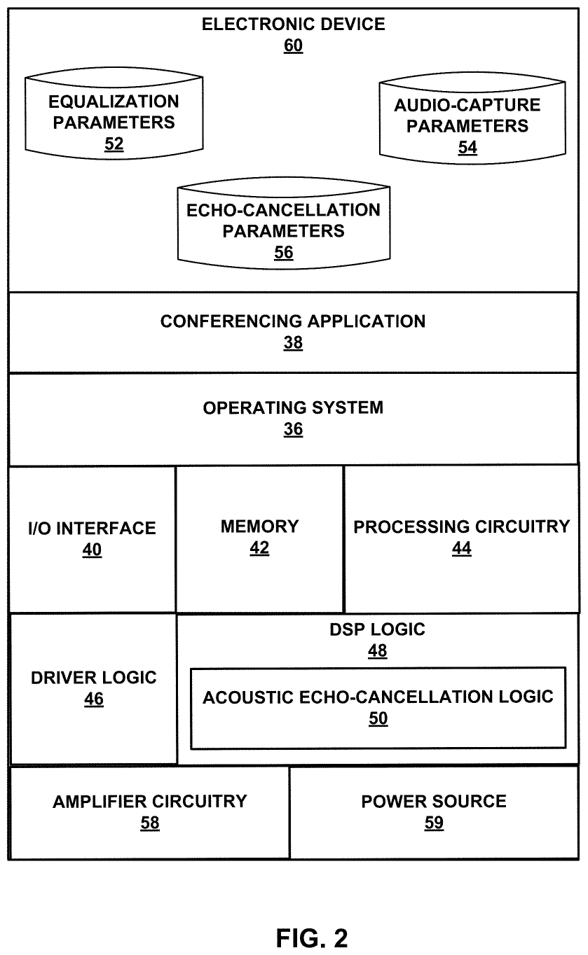

FIG. 2 is a block diagram illustrating an example of electronic device 60 of FIGS. 1A and 1B. Electronic device 60 implements one or more of the audio-data-manipulation techniques of this disclosure. In the example shown in FIG. 2, electronic device 60 includes memory 42 and processing circuitry 44 communicatively connected to memory 42. In some examples, memory 42 and processing circuitry 44 may be collocated to form a portion of an integrated circuit, or may be integrated into a single hardware unit, such as a system on a chip (SoC).

Processing circuitry 44 may include, be, or be part of one or more of a multi-core processor, a controller, a digital signal processor (DSP), an application specific integrated circuit (ASIC), a field-programmable gate array (FPGA), processing circuitry (e.g., fixed function circuitry, programmable circuitry, or any combination of fixed function circuitry and programmable circuitry) or equivalent discrete logic circuitry or integrated logic circuitry. Memory 42 may include any form of memory for storing data and executable software instructions, such as random-access memory (RAM), read only memory (ROM), programmable read only memory (PROM), erasable programmable read only memory (EPROM), electronically erasable programmable read only memory (EEPROM), and flash memory.

In some examples, processing circuitry 44 of electronic device includes a videoconferencing codec configured to manage audiovisual telephonic system 12A to run a videoconferencing session. For instance, in addition to a connected speaker module, processing circuitry 44 may be configured to control microphone 22, display device 18A, and/or other components of audiovisual conferencing system 12A (FIG. 1A) and/or audiovisual conferencing system 12C (FIG. 1B).

Memory 42 and processing circuitry 44 provide a computing platform for executing operation system 36. In turn, operating system 36 provides a multitasking operating environment for executing one or more software components installed on electronic device 60. Software components supported by the multitasking operating environment provided by operating system 36 represent executable software instructions that may take the form of one or more software applications, software packages, software libraries, hardware drivers, and/or Application Programming Interfaces (APIs). For instance, software components installed on electronic device 60 may display configuration menus on display device 18A for eliciting configuration information.

Processing circuitry 44 may connect via input/output (I/O) interface 40 to external systems and devices, such as to display 18A, image-capture system 20A, microphone array 22, speaker array 26, and the like. I/O interface 40 may also incorporate network interface hardware, such as one or more wired and/or wireless network interface controllers (NICs) for communicating via communication channel 16, which may represent a packet-switched network.

Conferencing application 38 implements functionalities that enable participation in a communication session over communication channel 16 using electronic device 60 as end-user hardware. Conferencing application 38 includes functionality to provide and present a communication session between two or more participants 30. For example, conferencing application 38 receives an inbound stream of audio data and video data from audiovisual conferencing system 12B and presents, via I/O interface 40, audio output data 28 and corresponding video output data to participant 30A via speaker module 26 or 27 and display device 18A, respectively. Similarly, conferencing application 38 captures audio input data 14 using microphone array 22 and image data using image-capture system 20A, and transmits audio/video data processed therefrom to audiovisual conferencing system 12B for presenting to participant 30C. Conferencing application 38 may include, for example, one or more software packages, software libraries, hardware drivers, and/or APIs for implementing the videoconferencing session.

Conferencing application 38 may process image data received via I/O interface 40 from image-capture system 20A and audio input data 14 received from microphone array 22, and may relay the processed video and audio feeds over communications channel 16 to other end-user hardware devices connected to the in-progress conferencing session (which, in the example of FIG. 1A, is a videoconferencing session). Additionally, conferencing application 38 may process video and audio feeds received over communications channel 16 as part of the videoconferencing session, and may enable other components of electronic device 60 to output the processed video data via display device 18A and the processed audio data via speaker module 26 or 27 (as audio output data 28) using I/O interface 40 as an intermediate relay.

Electronic device 60 may include a rendering engine configured to construct visual content to be output by display device 18A, using video data received over communications channel 16 and processed by conferencing application 38. In some examples, the rendering engine constructs content to include multiple video feeds, as in the case of picture-in-picture embodiments of display content 24. In the examples of FIGS. 1A and 1B, the rendering engine constructs display content 24 to include the video stream reflecting video data received from video presence device 18B over communications channel 16. In other examples, the rendering engine may overlay data of a second video stream (in the form of a video feedthrough) reflecting video data received locally from image-capture system 20A. In some examples, the rendering engine may construct display content 24 to include sections representing three or more video feeds, such as individual video feeds of two or more remote participants.

As shown in FIG. 2, electronic device 60 may optionally include amplifier circuitry 58. Amplifier circuitry 58 is configured to amplify audio signals for output to speaker module(s) 26 or 27 while the electronic device is coupled to the speaker module(s) 26 or 27. In some examples, speaker module(s) 26 or 27 may additionally or alternatively include amplifier circuitry.

In the example shown in FIG. 2, electronic device 60 includes driver logic 46 and DSP logic 48, which includes at least acoustic echo-cancellation logic 50. Any of driver logic 46, DSP logic 48, or acoustic echo-cancellation logic 50 may be implemented in hardware or as hardware-implemented software or firmware. One or more of driver logic 46, DSP logic 48, or acoustic echo-cancellation logic 50 may be implemented in an integrated circuitry, such as by being collocated with processing circuitry 44 and memory 42, or in another integrated circuit by being collocated with different memory and processing hardware. Although illustrated as separate logic, in some examples, two or more of driver logic 46, DSP logic 48, and acoustic echo-cancellation logic 50 may be implemented together.

Driver logic 46 may modify driver signals provided via I/O interface 40 to a connected speaker module 27 (FIG. 1B) based on parameters associated with speaker module 27, e.g., as determined by processing circuitry 44 based on one or more parameters associated with speaker module 27. For example, processing circuitry 44 may use a mapping of a configuration of connector pins of the connected speaker module to a particular parameter set available from equalization parameters 52. In other examples, processing circuitry 44 may use a mapping of data read from a memory of the connected speaker module to a particular parameter set available from equalization parameters 52. Equalization parameters 52 may include one or more of amplitude (e.g., expressed as function of frequency), a high-pass filter, a low-pass filter, notch filters, a Q factor of one or more filters, a filter amplitude, a phase, general fidelity, loudness-levelling, de-reverberation, etc. Equalization parameters 52 also may include a crossover frequency and/or crossover slope associated with audio signals to be provided to different drivers handling different frequency ranges (e.g., a tweeter and a midrange driver and/or a midrange driver and a woofer or subwoofer).

In turn, driver logic 46 may drive connected speaker module 27 according to the parameter set selected from equalization parameters 52 based on the mapping to the speaker parameters determined by processing circuitry 44. In this way, driver logic 46 may use equalization parameters 52 to drive connected speaker module 27 such that audio-output data 28 is rendered in a customized way with respect to the parameters associated with speaker module 27 so as to improve the quality of the resulting audio output.

Acoustic echo-cancellation logic 50 may map determined speaker parameters to respective parameter sets included in echo-cancellation parameters 56. Each parameter set may compensate for feedback or interference that audio output data 28 causes with respect to audio-input data 14, resulting at least in part from the speaker parameters (e.g., based on a size or other configurations of the particular speaker type). Acoustic echo-cancellation logic 50 may apply a given set of echo-cancellation parameters to compensate for identified coherence timings, for coherence thresholds with respect to audio-signal similarity, etc.

In some examples, one or more of equalization parameters 52, audio-capture parameters 54, or echo-cancellation parameters 56 may be stored locally at electronic device 60. In these examples, electronic device 60 may include one or more storage devices configured to store information within electronic device 60 during operation. The storage device(s) of electronic device 60, in some examples, are described as a computer-readable storage medium and/or as one or more computer-readable storage devices, such as a non-transitory computer-readable storage medium, and various computer-readable storage devices.

The storage device(s) of electronic device 60 may be configured to store larger amounts of information than volatile memory, and may further be configured for long-term storage of information. In some examples, the storage device(s) of electronic device 60 include non-volatile storage elements, such as solid-state drives (SSDs), magnetic hard discs, optical discs, floppy discs, flash memories, or forms of electrically programmable memories (EPROM) or electrically erasable and programmable (EEPROM) memories. Electronic device 60 may also include capabilities to receive from, access, and write to various types of removable, non-volatile storage devices, such as USB flash drives, SD cards, and the like.

In some examples, one or more of equalization parameters 52, audio-capture parameters 54, or echo-cancellation parameters 56 may be stored at an external (e.g., remote) device, such as a real or virtual server to which electronic device 60 is communicatively coupled via network interface card hardware of I/O interface 40. In these examples, one or more of driver logic 46, DSP logic 48, or acoustic echo-cancellation logic 50 may access and download parameter information on an as-needed basis over a packet-switched network via network-interface hardware of I/O interface 40. The real or virtual server may be hosted at a data center, server farm, server cluster, or other high-storage-capacity facility.

Electronic device 60 further includes power source 59. Power source 59 is configured to provide electrical power to both electronic device 60 and a connected speaker module (e.g., speaker module 26 or 27) while electronic device 60 is removably coupled to (e.g., received within) the speaker module. Power source 59 may include a wired connection for an electrical outlet and associated circuitry, and/or an internal rechargeable battery. Including the power source for the connected speaker module(s) within electronic device 60 enables intelligent detection of electrical faults (e.g., shorts, partial discharges, etc.) for components of the speaker module.

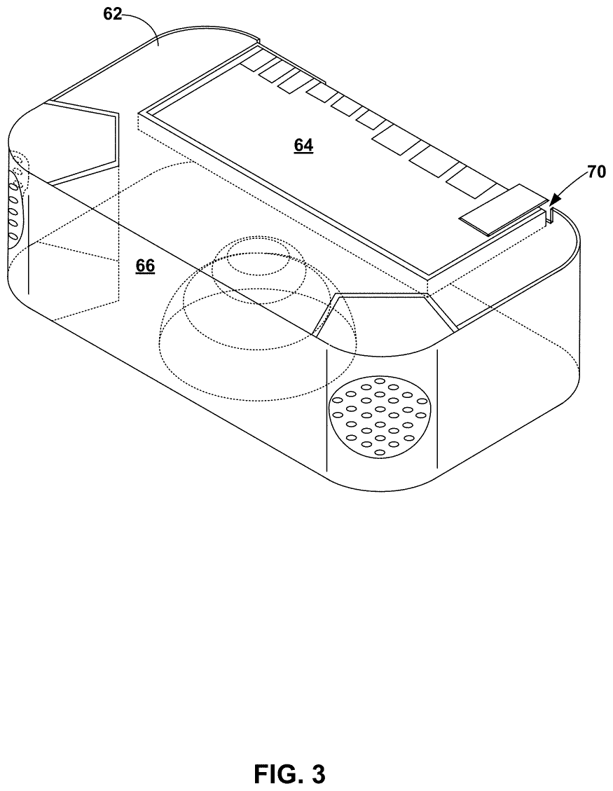

FIGS. 3-7 illustrate various example configurations of speaker modules and electronic device 60 of FIGS. 1A-2, in accordance with this disclosure. For instance, FIG. 3 illustrates an example passive speaker module 62 and an example modular electronic device 64. Passive speaker module 62 is an example of speaker modules 26 and 27 of FIGS. 1A and 1B, and modular electronic device 64 is an example of electronic device 60 of FIGS. 1A-2.

Modular electronic device 64 is depicted in FIG. 3 as being removably coupled to passive speaker module 62, according to one or more techniques of this disclosure. For instance, passive speaker module 62 includes an external housing 66 that defines a cavity or slot 70 configured (e.g., sized) to receive electronic device 64. As described above, a portion of the external housing 66 located within cavity 70 may include a set of connector pins (not shown in FIG. 3) or other connection mechanism (e.g., a spring hinge) configured to interconnect with and retain electronic device 64. In other examples, electronic device 64 is configured to removably couple to passive speaker module 62 via a communicative coupling, such as a wireless pairing.

In this way, the systems and techniques of this disclosure provide the dual benefits of improving audio quality while also reducing costs for both producers and consumers. For instance, by being able to removably couple to multiple different types (e.g., shapes, sizes, etc.) of speaker modules and/or physical environments, electronic device 64 is configured to determine customized audio-configuration settings (e.g., echo-cancellation settings, etc.) that complement the speaker module in a way that improves the quality of the subsequently rendered audio. Meanwhile, by lacking individual, fully-functional integrated electronic circuitry, the various passive speaker modules may be substantially less complex and less expensive to manufacture. Even further, the modular design of the systems described herein enables end-users or information technology departments to more easily and less expensively customize a videoconferencing system according to their unique requirements. In another sense, the consumer may more easily and less expensively upgrade the videoconferencing system when desired, such as by exchanging a smaller passive speaker module for a larger passive speaker module at a substantially reduced cost as compared to fully functional speaker modules of similar corresponding sizes.

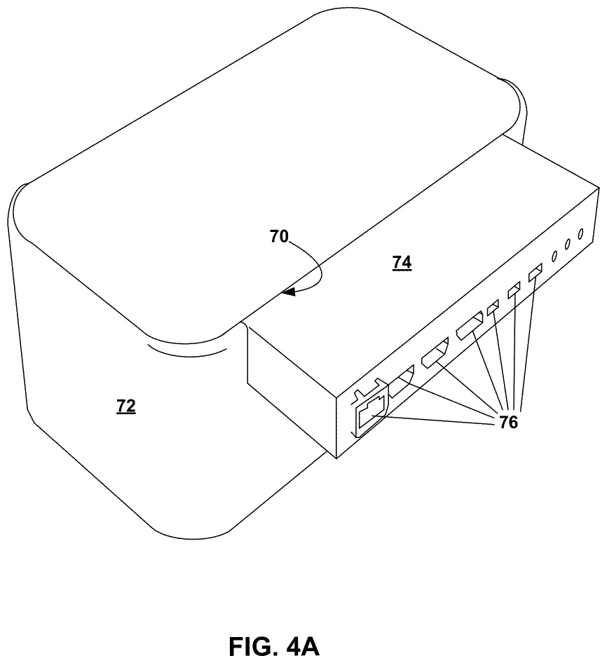

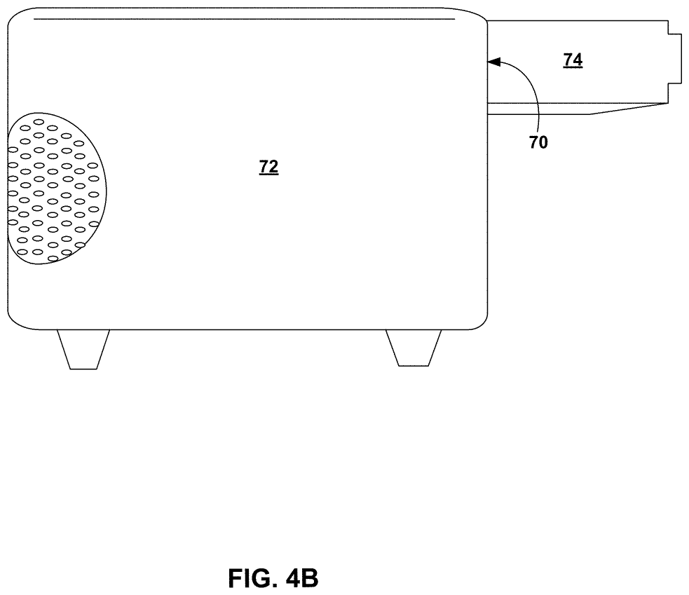

FIG. 4A is a perspective overhead view, and FIG. 4B is a side view, of another example passive speaker module 72 and a modular electronic device 64. Speaker module 72 is an example of speaker module 62, and electronic device 74 is an example of electronic device 64, except for the differences noted herein.

Similar to speaker module 62 of FIG. 3, passive speaker module 72 of FIGS. 4A and 4B defines a slot or cavity 70 configured (e.g., sized) to receive electronic device 74. However, as depicted, when received within slot 70, a portion of electronic device 74 protrudes outward from the external housing of passive speaker module 72. In such examples, passive speaker module 72 may be smaller in size (and, e.g., audio-output range) than passive speaker module 62. However, both passive speaker module 62 and passive speaker module 72 may be configured to receive a common electronic device 64 or 74.

As shown in FIG. 4A, electronic device 74 (or any other modular electronic device of this disclosure) defines a plurality of input ports 76 for connecting passive speaker module 72 to various other components of audiovisual telephonic system 12A. For instance, input ports 76 may include, as non-limiting examples, one or more ethernet port, one or more HDMI ports, one or more USB ports, one or more audio-jack ports, one or more RCA ports, or the like.

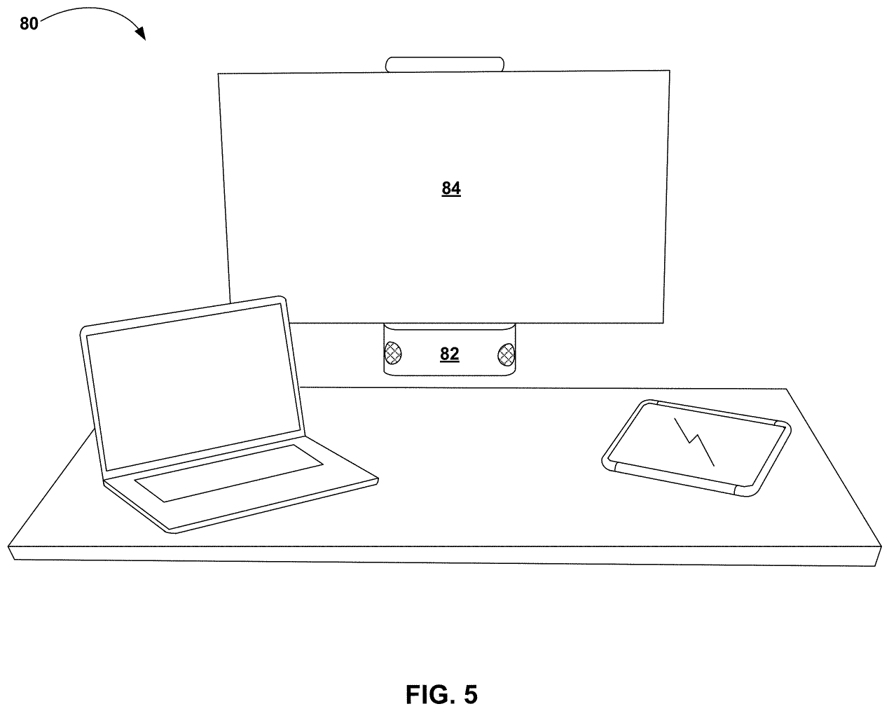

FIG. 5 illustrates an example desk setup 80, which is an example of audiovisual telephonic system 12A of FIG. 1A. In particular, FIG. 5 depicts a passive speaker module 82 removably coupled to an electronic device (not shown) that is further coupled to a display device 84. Display device 84 is an example of display device 18A of FIGS. 1A and 1B, and is depicted in FIG. 5 as a television screen or computer monitor. For instance, the electronic device may be connected to display device 84 via a wired connection between one of ports 76 (FIG. 4A) and a corresponding port on display device 84, and then the electronic device may be slotted into the cavity or slot on the backside of passive speaker module 82 (not shown).

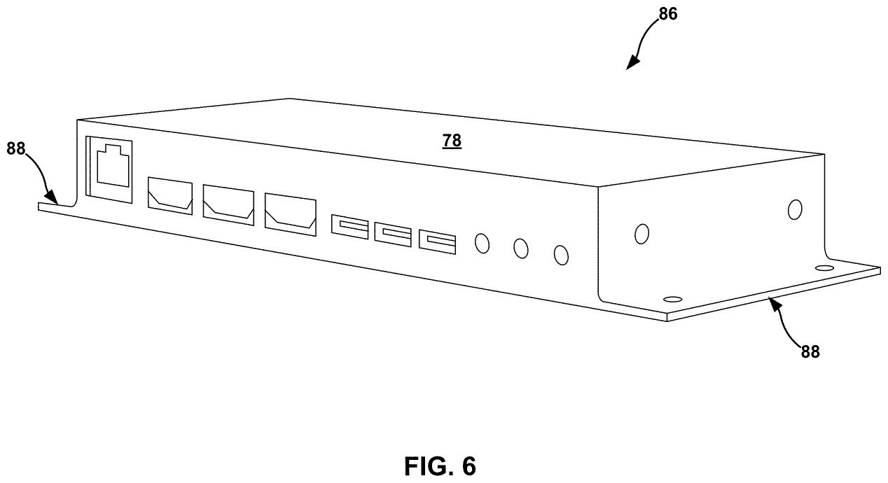

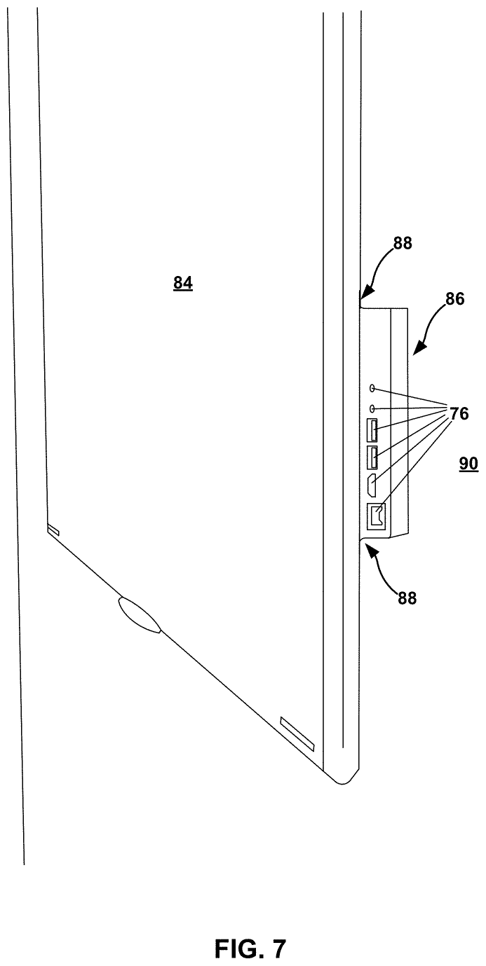

FIGS. 6 and 7 illustrate another example electronic device 86, which is an example of electronic device 60 of FIG. 2. As shown in FIGS. 6 and 7, an external housing 78 of electronic device 86 defines a pair of integrated mounting brackets 88 for, e.g., mounting electronic device 86 onto a wall or other surface. For instance, as shown in FIG. 7, electronic device 86 may be mounted onto a wall 90 near or behind display device 84. In some such examples, one or more external speakers (e.g., passive speakers and/or fully functional speakers) may be coupled to electronic device 86, either via a wireless paring connection, or via one or more of the connector ports 76 of electronic device 86. In other examples, however, display device 84 itself comprises the speaker module. For instance, display device 84 may include a television screen having integrated audio-output components. In such examples, electronic device 86 may be coupled to display screen 84, such as being received within a slot behind the display device, via connector ports 76, or via a wireless data connection, in order to drive the audio as rendered and produced by display device 84. In any of the above examples, electronic device 86 is configured to determine one or more parameters of the audio-output capabilities of display device 84 and/or its physical environment, and set echo-cancellation settings and/or other audio-configuration settings for the audio to be produced.

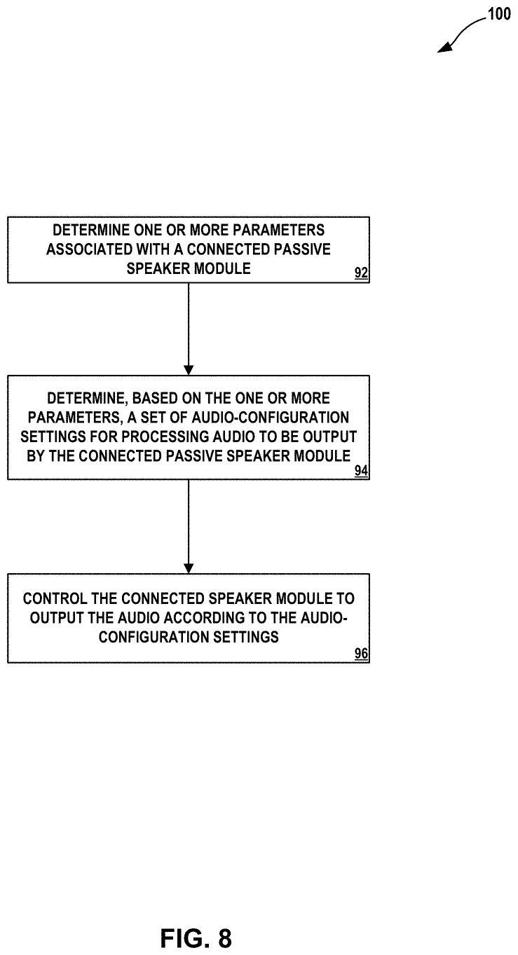

FIG. 8 is a flowchart illustrating an example of an audio-configuration process 100 for a videoconferencing system, in accordance with the techniques of this disclosure. Process 100 of FIG. 8 is described primarily with respect to electronic device 60 of FIGS. 1A-2, however, the techniques may be performed by any suitable electronic device.

An electronic device 60 may be removably coupled to a passive speaker module. For instance, the passive speaker module may include a cavity or slot configured to receive electronic device 60 to physically and electronically connect to electronic device 60. In other examples, electronic device 60 may be removably coupled to a passive speaker module via a wireless-communication connection, such as a wireless “pairing” between the respective devices.

When removably coupled to the passive speaker module, electronic device 60 (e.g., via processing circuitry 44) is configured to determine one or more parameters associated with the passive speaker module (92). The parameters may indicate dimensions, configurations, or other specifications of the passive speaker module itself and/or a physical environment in which the speaker module is located.

In some examples, electronic device 60 may determine the parameters by receiving an indication of the parameters from the passive speaker module. For instance, the passive speaker module may include a unique configuration (e.g., number and arrangement) of connector pins configured to engage with electronic device 60, wherein the configuration of pins encodes an indication of the parameters and conveys the indication to electronic device 60 when electronic device 60 connects to the pins. In another example, the passive speaker device may include a memory chip storing data that encodes an indication of the parameters, such that electronic device 60 may read the data from the memory chip when connected to the passive speaker module.

Based on the one or more parameters associated with the passive speaker module, electronic device 60 is configured to determine a corresponding set of audio-configuration settings (94). The audio-configuration settings indicate specifications for modifying audio data to be output by the passive speaker module in a way that complements the parameters associated with the passive speaker module so as to improve audio quality for a user of the videoconferencing system. For instance, the audio-configuration settings may include at least a set of customized audio-cancellation settings for a type of speaker module to which the connected speaker module belongs, and/or for a type of physical environment in which the connected speaker module is located. After selecting the set of audio-configuration settings, electronic device is configured to control the connected passive speaker module to render and output the custom-modified audio (96).

The techniques described in this disclosure may be implemented, at least in part, in hardware, software, firmware or any combination thereof. For example, various aspects of the described techniques may be implemented within one or more processors, including one or more microprocessors, DSPs, application specific integrated circuits (ASICs), field programmable gate arrays (FPGAs), processing circuitry (e.g., fixed function circuitry, programmable circuitry, or any combination of fixed function circuitry and programmable circuitry) or equivalent discrete logic circuitry or integrated logic circuitry, as well as any combinations of such components. The term “processor” or “processing circuitry” may generally refer to any of the foregoing logic circuitry, alone or in combination with other logic circuitry, or any other equivalent circuitry. A control unit comprising hardware may also perform one or more of the techniques of this disclosure.

Such hardware, software, and firmware may be implemented within the same device or within separate devices to support the various operations and functions described in this disclosure. In addition, any of the described units, modules or components may be implemented together or separately as discrete but interoperable logic devices. Depiction of different features as modules or units is intended to highlight different functional aspects and does not necessarily imply that such modules or units must be realized by separate hardware or software components. Rather, functionality associated with one or more modules or units may be performed by separate hardware or software components or integrated within common or separate hardware or software components.

As described by way of various examples herein, the techniques of the disclosure may include or be implemented in conjunction with a video-communications system. The techniques described in this disclosure may also be embodied or encoded in a computer-readable medium, such as a computer-readable storage medium, containing instructions. Instructions embedded or encoded in a computer-readable storage medium may cause a programmable processor, or other processor, to perform the method, e.g., when the instructions are executed. Computer readable storage media may include random access memory (RAM), read only memory (ROM), programmable read only memory (PROM), erasable programmable read only memory (EPROM), electronically erasable programmable read only memory (EEPROM), flash memory, a hard disk, a CD-ROM, a floppy disk, a cassette, magnetic media, optical media, or other computer-readable media.

As described by way of various examples herein, the techniques of the disclosure may include or be implemented in conjunction with an artificial reality system. As described, artificial reality is a form of reality that has been adjusted in some manner before presentation to a user, which may include, e.g., a virtual reality (VR), an augmented reality (AR), a mixed reality (MR), a hybrid reality, or some combination and/or derivatives thereof. Artificial reality content may include completely generated content or generated content combined with captured content (e.g., real-world photographs). The artificial reality content may include video, audio, haptic feedback, or some combination thereof, and any of which may be presented in a single channel or in multiple channels (such as stereo video that produces a three-dimensional effect to the viewer).

Additionally, in some examples, artificial reality may be associated with applications, products, accessories, services, or some combination thereof, that are, e.g., used to create content in an artificial reality and/or used in (e.g., perform activities in) an artificial reality. The artificial reality system that provides the artificial reality content may be implemented on various platforms, including a head-mounted display (HMD) connected to a host computer system, a standalone HMD, a videoconferencing system, a mobile device or computing system, or any other hardware platform capable of providing artificial reality content to one or more viewers.

What is claimed is:

1. An electronic device for a conferencing system, the electronic device comprising:
a device housing configured to removably couple to each of a plurality of speaker modules; and
processing circuitry disposed within the device housing, wherein the processing circuitry is configured to:
determine one or more parameters associated with a speaker module of the plurality of speaker modules after the device housing is coupled to the speaker module; and
determine, based on the one or more parameters associated with the speaker module, a set of corresponding audio-configuration settings for processing audio during operation of the conferencing system.

2. The electronic device of claim 1, wherein the audio-configuration settings comprise echo-cancellation settings.

3. The electronic device of claim 1, wherein the audio-configuration settings comprise at least one of frequency, phase, loudness, or delay settings for processing the audio signals output from the amplifier circuitry to the speaker module.

4. The electronic device of claim 1, wherein the processing circuitry is configured to determine the one or more parameters associated with the speaker module based at least in part on a configuration of connector pins of the speaker module, wherein the device housing is configured to removably couple to the speaker module by interconnecting with the connector pins.

5. The electronic device of claim 4, wherein the connector pins encode a binary identifier representing a type of the speaker module.

6. The electronic device of claim 4, wherein the connector pins comprise pogo pins.

7. The electronic device of claim 1, wherein the processing circuitry is further configured to:
determine, from the speaker module while the device housing is removably coupled to the speaker module, one or more physical parameters of an environment in which the speaker module is located; and
determine, based on the one or more physical parameters of the environment, the set of corresponding audio-configuration settings.

8. The electronic device of claim 1, wherein each of the plurality of speaker modules comprises a speaker box having a speaker size that is different from each of the other speaker modules of the plurality of speaker modules.

9. The electronic device of claim 8, wherein each of the plurality of speaker modules further comprises amplifier circuitry configured to drive one or more drivers of the speaker module.

10. The electronic device of claim 1, wherein the speaker module comprises a stereo speaker, and wherein the processing circuitry is further configured to:
determine a relative location of a user of the conferencing system within a room in which the speaker module is located; and
control the stereo speaker to improve quality of the audio for the user.

11. The electronic device of claim 1, wherein the speaker module comprises a memory chip storing the one or more parameters associated with the speaker module, and wherein the processing circuitry is configured to determine the one or more parameters associated with the speaker module based on information retrieved from the memory chip.

12. The electronic device of claim 1, wherein the processing circuitry comprises a videoconferencing codec configured to control the speaker module, a microphone, and a video monitor.

13. The electronic device of claim 1, wherein the speaker module defines a slot sized to receive the device housing, and wherein the electronic device is configured to removably couple to the speaker module while received within the slot.

14. The electronic device of claim 1, wherein the speaker module comprises a first speaker module of the plurality of speaker modules, and wherein the plurality of speaker modules further comprises a second speaker module in data communication with the first speaker module, and wherein the processing circuitry is configured to control an operation of the second speaker module while the electronic device is coupled to the first speaker module.

15. The electronic device of claim 1, wherein the device housing comprises a spring hinge, and wherein the electronic device is configured to removably couple to the speaker module via the spring hinge.

16. The electronic device of claim 1, wherein the speaker module comprises a display.

17. The electronic device of claim 1, further comprising amplifier circuitry disposed within the device housing, wherein the amplifier circuitry is configured to amplify audio signals for output to a speaker module of the plurality of speaker modules while the electronic device is coupled to the speaker module.

18. A conferencing system comprising:
a speaker module; and
an electronic device comprising:
a device housing configured to removably couple to the speaker module; and
processing circuitry disposed within the device housing, wherein the processing circuitry is configured to:
determine one or more parameters associated with the speaker module after the device housing is coupled to the speaker module; and
determine, based on the one or more parameters associated with the speaker module, a set of corresponding audio-configuration settings for processing audio during operation of the conferencing system.

19. The system of claim 18, wherein the audio-configuration settings comprise echo-cancellation settings.

20. The system of claim 18, wherein the audio-configuration settings comprise at least one of frequency, phase, or delay settings for processing the audio signals output from the amplifier circuitry to the speaker module.

21. The system of claim 18, wherein the processing circuitry is configured to determine the one or more parameters associated with the speaker module based at least in part on a configuration of connector pins of the speaker module, wherein the device housing is configured to removably couple to the speaker module by interconnecting with the connector pins.

22. A non-transitory, computer-readable medium comprising instructions that, when executed by processing circuitry, cause the processing circuitry to:
determine one or more parameters associated with a speaker module after an electronic device comprising the processing circuitry is removably coupled to the speaker module; and
determine, based on the one or more parameters associated with the speaker module, a set of corresponding audio-configuration settings for processing audio during operation of a conferencing system comprising the speaker module, wherein the audio-configuration settings comprise at least echo-cancellation settings.
